(19) United States
(12) Patent Application Publication
(10) Pub. No.: US 2012/0193664 A1
(43) Pub. Date: Aug. 2, 2012

(54) SEMICONDUCTOR LIGHT EMITTING STRUCTURE

(75) Inventor: Jhih-Han LIN, Taipei City (TW)

(73) Assignee: LEXTAR ELECTRONICS CORP., Hsinchu (TW)

(21) Appl. No.: 13/358,489

(22) Filed: Jan. 25, 2012

Related U.S. Application Data
(60) Provisional application No. 61/437,921, filed on Jan. 31, 2011.

(30) Foreign Application Priority Data
Sep. 26, 2011 (TW) 100134586

(51) Int. Cl. H01L 33/22

(52) U.S. Cl. 257/98; 257/E33.062

(57) ABSTRACT

A semiconductor light emitting structure includes a substrate, a first semiconductor layer, an active layer, a second semiconductor layer and two electrodes. The substrate has a top surface and a bottom surface. The top surface is not parallel to the bottom light emitting surface of the active layer. The first semiconductor layer is disposed on the top surface. The active layer is disposed on at least one portion of the first semiconductor layer. The second semiconductor layer is disposed on the active layer. In an embodiment, the top surface can be realized by an oblique surface, a curved surface or a zigzag surface.

This application claims the benefit of U.S. provisional application Ser. No. 61/437,921, filed Jan. 31, 2011, and the benefit of Taiwan application Serial No. 100134586, filed Sep. 26, 2011 the subject matters of which are incorporated herein by reference.

### BACKGROUND OF THE INVENTION

1. Field of the Invention

The invention relates in general to light emitting device, and more particularly to a semiconductor light emitting structure.

2. Description of the Related Art

Due to advantages of long lifetime, small volume, great resistance to vibration, low heat emission, and low power consumption, light emitting diodes (LEDs) have been extensively applied in various home appliances and instruments as indicators or light sources. With recent development towards multicolor and high illumination, the applications of the LEDs are extended to large-sized outdoor billboards, traffic lights, and so forth. In the future, the LEDs are likely to become power-saving and environment-protecting light sources in replacement of tungsten filament lamps and mercury vapor lamps.

Light emitting diode is a semiconductor light emitting element, which mainly includes a substrate, an epitaxy layer, and two external electrodes. The epitaxy layer further includes two semiconductor layers having N-type and P-type dopants, and an active layer located between the two semiconductor layers. When a forward bias voltage is applied to the external electrode, the current flows through the semiconductor layers, and electrons and electron holes are combined in the active layer, thus the active layer emits light.

However, the index of refraction of the substrate is higher than that of the semiconductor layer, the light emitting toward the substrate is transmitted into the substrate and trapped within the substrate, as light within the substrate is reflected at the interface between the semiconductor layer and the substrate when the incident angle of light is larger than a critical angle. Since the light cannot be emitted to the outside of the substrate, the light extraction efficiency of LED is lowered.

### SUMMARY OF THE INVENTION

The disclosure is directed to a semiconductor light emitting structure enabling light generated from the active layer to be scattered or reflected at the interface between the semiconductor layer and the substrate so that the light can be emitted to the outside, which enhances the light extraction efficiency.

In accordance with the present invention, at least a portion of the top surface of the substrate facing the light emitting surface of the active layer in the light emitting structure is inclined with respect to the light emitting surface of the active layer. The profile of the inclined surface of the top surface of the substrate may be in the form of a flat surface, a curved surface, an overall concave or convex surface, a faceted surface, a zigzag surface, a textured surface, or a combination of these surfaces. The structured top surface of the substrate may include at least an inclined surface that is two dimensionally varying or three-dimensionally varying across the plane of the surface of the substrate. Various aspects of the present invention are further described below.

According to one aspect of the present disclosure, a semiconductor light emitting structure includes a substrate, a first semiconductor layer, an active layer and a second semiconductor layer. The substrate has a top surface and a bottom surface. The top surface is not parallel to the bottom surface. The first semiconductor layer is disposed on the top surface. The active layer is disposed on at least one portion of the first semiconductor layer. The second semiconductor layer is disposed on the active layer.

According to another aspect of the present disclosure, a semiconductor light emitting structure includes a substrate, a patterned structure, a first semiconductor layer, an active layer and a second semiconductor layer. The substrate has a top surface and a bottom surface. The top surface is not parallel to the bottom surface. The top surface can be realized by a curved surface, an oblique surface or a zigzag surface. The patterned structure protrudes from or indents into the top surface to rough the top surface. The first semiconductor layer is disposed on the roughed top surface. The active layer is disposed on at least one portion of the first semiconductor layer. The second semiconductor layer is disposed on the active layer.

According to yet another aspect of the present disclosure, semiconductor light emitting structure includes a first semiconductor layer, an active layer and a second semiconductor layer. The first semiconductor layer has a top surface and a bottom surface. The top surface is not parallel to the bottom surface. The active layer is disposed on the top surface of the first semiconductor layer. The second semiconductor layer is disposed on the active layer.

According to another aspect of the present disclosure, a semiconductor light emitting structure includes a first semiconductor layer, a patterned structure, an active layer, a second semiconductor layer and two opposite side electrodes. The first semiconductor layer has a top surface and a bottom surface. The top surface is not parallel to the bottom surface. The top surface can be realized by a curved surface, an oblique surface or a zigzag surface. The patterned structure protrudes from or indents into the top surface to rough the top surface. The active layer is disposed on the roughed top surface of the first semiconductor layer. The second semiconductor layer is disposed on the active layer.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIGS. 1A and 1B are cross-sectional views showing a semiconductor light emitting structure according to an embodiment of the invention.

FIGS. 2A and 2B are cross-sectional views showing a semiconductor light emitting structure according to an embodiment of the invention.

FIGS. 3A and 3B are cross-sectional views showing a semiconductor light emitting structure according to an embodiment of the invention.

FIGS. 4A and 4B are cross-sectional views showing a semiconductor light emitting structure according to an embodiment of the invention.

FIGS. 5A and 5B are cross-sectional views showing a semiconductor light emitting structure according to an embodiment of the invention.

FIGS. 6A-6C are cross-sectional views showing a semiconductor light emitting structure according to an embodiment of the invention.

FIGS. 7A-7C are cross-sectional views showing a semiconductor light emitting structure according to an embodiment of the invention.

FIGS. 8A-8F are cross-sectional views showing a semiconductor light emitting structure according to an embodiment of the invention.

FIG. 9 is a cross-sectional view showing a semiconductor light emitting structure according to an embodiment of the invention.

FIGS. 10A and 10B are cross-sectional views showing a semiconductor light emitting structure according to an embodiment of the invention.

FIGS. 11A and 11B are cross-sectional views showing a semiconductor light emitting structure according to an embodiment of the invention.

FIGS. 12A and 12B are cross-sectional views showing a semiconductor light emitting structure according to an embodiment of the invention.

FIGS. 13A and 13B are cross-sectional views showing a semiconductor light emitting structure according to an embodiment of the invention.

FIGS. 14A-14C are cross-sectional views showing a semiconductor light emitting structure according to an embodiment of the invention.

FIGS. 15A-15C are cross-sectional views showing a semiconductor light emitting structure according to an embodiment of the invention.

FIGS. 16A-16F are cross-sectional views showing a semiconductor light emitting structure according to an embodiment of the invention.

FIGS. 17A-17H are top views showing a semiconductor light emitting structure according to the first and second embodiments of the invention.

FIGS. 18A-18E are top views showing a semiconductor light emitting structure according to the third embodiments of the invention.

FIGS. 19A-19H and 20A-20H are schematic views showing a patterned structure according to an embodiment of the invention.

FIGS. 21A and 21B are schematic views showing taper portions whose center lines substantially perpendicular to the top surface or the bottom surface of the first semiconductor layer.

### DETAILED DESCRIPTION OF THE INVENTION

According to a semiconductor light emitting structure disclosed in an embodiment of the disclosure, light from the active layer entering the interface between the semiconductor layer (p-type or n-type) and the substrate at an angle larger than the critical angle can be scattered or reflected by the inclined top surface and/or the patterned structure formed on the inclined top surface. Since the interface between the semiconductor layer and the substrate is not a horizontal plane with respect to the active layer of horizontal plane, the effects of light scattering or light reflecting notably increase so that the light extraction efficiency increases accordingly.

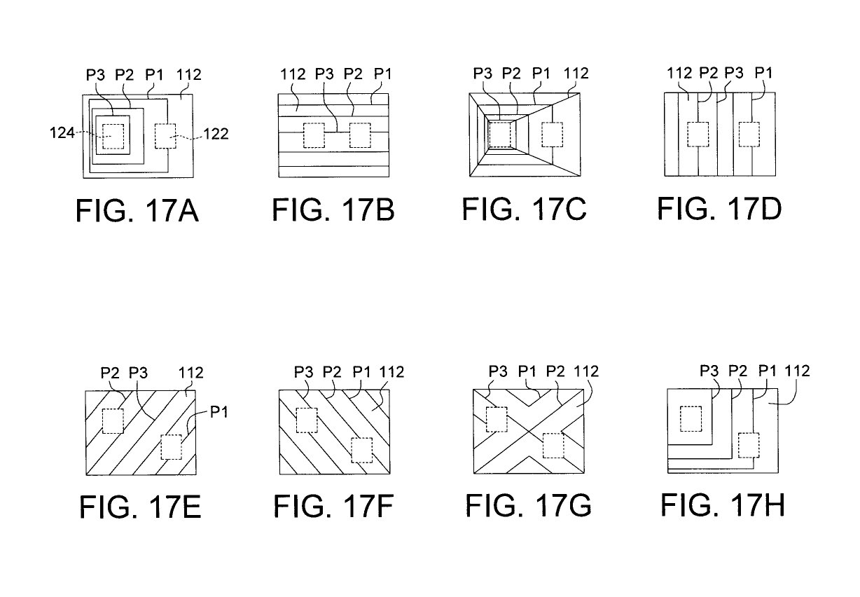

In the following first and second type embodiments, a sapphire substrate, a SiC substrate or a silicon substrate is used as a carrier, for example, on which a gallium nitride-base epitaxy layer including a n-type semiconductor layer, an active layer and a p-type semiconductor layer is formed in order. By etching a portion of the p-type semiconductor layer until the surface of the n-type semiconductor layer is exposed. A p-side electrode is formed on the surface of the p-type semiconductor layer and a n-side electrode is formed on the exposed surface of the n-type semiconductor layer so that two respective electrodes are placed at two diagonally opposite corners or two opposite sides of the semiconductor structure in a square form, as shown in the top view of the semiconductor layer of FIGS. 17A-17H.

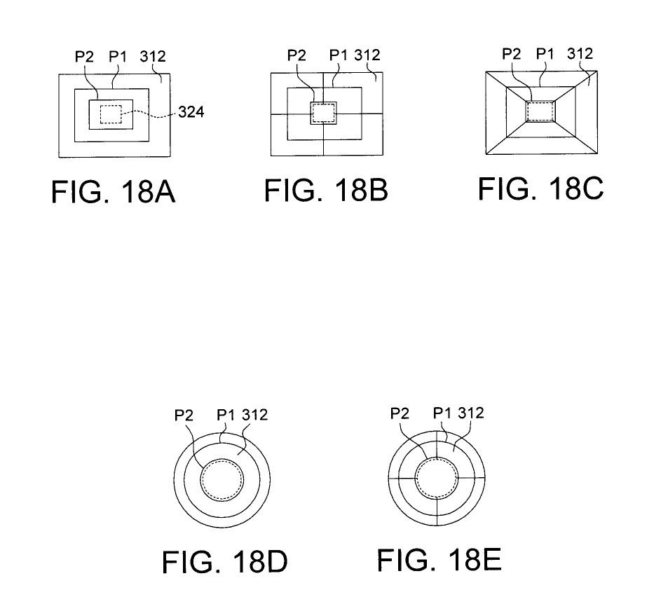

In the following third and fourth type embodiments, a gallium arsenide-base epitaxy layer including an n-type semiconductor layer, an active layer and a p-type semiconductor layer is formed in order, for example. Two opposite electrodes are formed on a top surface of the p-type semiconductor layer and a bottom surface of the n-type semiconductor layer, respectively. One electrode (p-side or n-side electrode) is shown in the top view of the semiconductor layer of FIGS. 18A-18E.

### First Type Embodiments

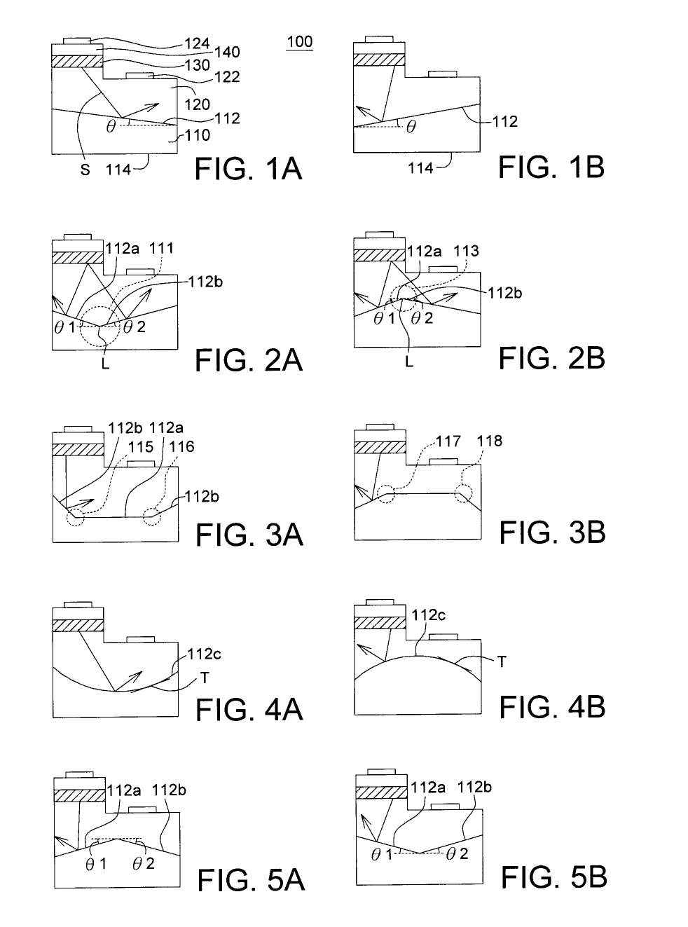

Referring to FIGS. 1A and 1B. FIGS. 1A and 1B are cross-sectional views showing a semiconductor light emitting structure according to an embodiment of the invention. The semiconductor light emitting structure 100 includes a substrate 110, a first semiconductor layer 120, an active layer 130, a second semiconductor layer 140 and two electrodes 122 and 124. The substrate 110 has a top surface 112 and a bottom surface 114. The top surface 112 is not parallel to the bottom of the active layer 130 (or the bottom surface 114, as the active layer is generally parallel to the bottom surface 114). The first semiconductor layer 120 is disposed on the top surface 112. The active layer 130 is disposed on at least one portion of the first semiconductor layer 120. The second semiconductor layer 140 is disposed on the active layer 130. In an embodiment, the top surface 112 can be realized by an inclined surface, which inclines to the left or to the right. The inclined angle θ of the top surface 112 is about 5˜30 degree or more relative to the bottom surface of the active layer 130. The light emitting from the active layer 130 to the inclined top surface 112 will be scattered or reflected to left side or right side of the semiconductor light emitting structure 100 to avoid the electrodes 122 and 124 on the top side of the semiconductor light emitting structure 100.

Referring to FIGS. 2A and 2B. FIGS. 2A and 2B are cross-sectional views showing a semiconductor light emitting structure according to an embodiment of the invention. The semiconductor light emitting structure of the present embodiment is formed in the similar manner as the semiconductor light emitting structure 100 of FIGS. 1A and 1B, wherein same indicated references are omitted. The different part between embodiments is that the top surface has an overall concave profile with an oblique indentation portion 111 or an overall convex profile with an oblique protruding portion 113, which inclines to the left and to the right. The indentation portion 111 or the protruding portion 113 has an overall concave or convex surface having an inclined surface 112a and a second inclined surface 112b meet at an intersection line L. (For a three-dimensionally varying substrate top surface, inclined surfaces could meet at a point.) The inclined angles θ1 and θ2 of the first inclined surface 112a and the second inclined surface 112b are about 5˜30 degree or more relative to the bottom surface 114. The light emitting from the active layer 130 to the inclined top surface 112 will be scattered or reflected to left side and right side of the semiconductor light emitting structure to avoid the electrodes 122 and 124 on the top side of the semiconductor light emitting structure 100.

Referring to FIGS. 3A and 3B. FIGS. 3A and 3B are cross-sectional views showing a semiconductor light emitting structure according to an embodiment of the invention. The semiconductor light emitting structure of the present embodiment is formed in the similar manner as the semiconductor light emitting structure 100 of FIGS. 1A and 1B, same indicated references are omitted. The different part between embodiments is that the top surface is an overall concave or convex surface. In the illustrated embodiment, the concave surface has at least two inclined portions 112b and the overall convex surface has at least two inclined portions 112b, but the number is not limited. Each of the inclined portions 112b or the inclined portions 112b meets a surface 112a at a respective intersection line L. In the illustrated embodiment, the surface 112a is shown to be parallel to the bottom light emitting surface of the active layer, but the surface 112a may also be inclined as well. The inclined angles of the surface 112a and the inclined surface 112b are about 5˜30 degree or more relative to the bottom light emitting surface. The light emitting from the active layer 130 to the concave top surface will be scattered or reflected to left side and right side of the semiconductor light emitting structure 100 to avoid the electrodes 122 and 124 on the top side of the semiconductor light emitting structure 100.

It is noted that the foregoing embodiments of concave and convex substrate top surface 112 are also representations of faceted surfaces, given that the concave and convex surfaces each comprises flat facets making up the overall surface 112.

Please note that zigzag characterizes a surface that could vary from a flat surface tilting above a horizon to a flat surface tilting below a horizon, and/or from concave to convex, or vice versa. The zigzag surface 112 is another representation of a faceted surface.]

Referring to FIGS. 4A and 4B. FIGS. 4A and 4B are cross-sectional views showing a semiconductor light emitting structure according to an embodiment of the invention. The semiconductor light emitting structure of the present embodiment is formed in the similar manner as the semiconductor light emitting structure 100 of FIGS. 1A and 1B, wherein same indicated references are omitted. The different part between embodiments is that the top surface is a continuous curved surface 112c. The slope on each tangential line T of the curved surface 112c is gradually increased or decreased from one side to another side to form a concave curve or a convex curve, as shown in FIGS. 4A and 4B. The inclined angles of the slope on each tangential line T of the curve surface 112c is in the range of about 0˜30 degree or more relative to the bottom surface 114. The light emitting to the curve surface 112c will be scattered or reflected to left side or right side of the semiconductor light emitting structure 100 to avoid the electrodes 122 and 124 on the top side of the semiconductor light emitting structure 100.

It is noted that the curved surface embodiments depicted in FIGS. 4A and 4B may be deemed to be having a surface profile that comprises flat surfaces joined to form an overall curved surface (concave or convex). In other words, the “facets” form an overall curved surface, as shown in FIGS. 2A, 2B, 3A and 3B.

Referring to FIGS. 5A and 5B. FIGS. 5A and 5B are cross-sectional views showing a semiconductor light emitting structure according to an embodiment of the invention. Exception that FIGS. 2A and 2B show the first inclined surface 112a and the second inclined surface 112b having different inclined angles, that is, θ1≠θ2, the semiconductor light emitting structure of the present embodiment shows that the indentation portion 111 or the protruding portion 113 is located near or at the middle of the substrate 110, wherein the first inclined surface 112a and the second inclined surface 112b may have the same inclined angles, that is, θ1=θ2. The inclined angles of the first inclined surface 112a and the second inclined surface 112b are about 5˜30 degree or more relative to the bottom surface 114. It is noted that θ1 does not need to be equal to θ2 for the protrusion portion or indentation portion to be in the middle of the substrate, or when θ1=θ2, the protrusion portion or indentation portion does not need to be in the middle of the substrate.

According to the first embodiments, the top surface 112 of the substrate 110 can be realized by an inclined surface, which may be structured in the form of at least an inclined surface, which may be part of flat surface, a curved surface, an overall concave or convex surface, a faceted surface, a zigzag surface. Since the interface between the first semiconductor layer 120 and the substrate 110 is not a horizontal plane with respect to the light emitting surface of the active layer 130, light scattering and/or reflecting to outside is notably increased so that the light extraction efficiency increases accordingly.

### Second Type Embodiments

The inclined surface of the substrate top surface may be provided by micro-structures in a textured surface. Exemplary embodiments are discussed below.

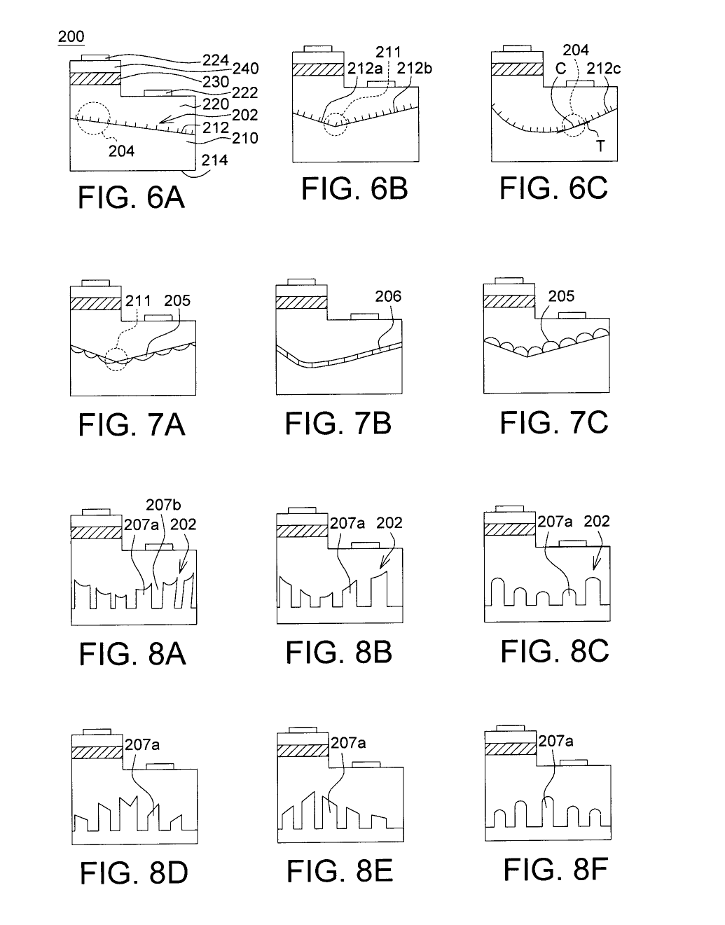

Referring to FIGS. 6A-6C. FIGS. 6A-6C are cross-sectional views showing a semiconductor light emitting structure according to an embodiment of the invention. The semiconductor light emitting structure 200 includes a substrate 210, a patterned structure 202, a first semiconductor layer 220, an active layer 230, a second semiconductor layer 240 and two electrodes 222 and 224. The substrate 210 has a top surface 212 and a bottom surface 214. The top surface 212 is not parallel to the bottom light emitting surface ## of the active layer 230 As in the previous embodiment, the op surface 212 can be realized by, for example, overall a curved surface, an inclined surface or a zigzag surface, etc. The patterned structure 202 protrudes from or indents into the top surface 212 to roughen the top surface 212. The first semiconductor layer 220 is disposed on the roughened top surface 212. The active layer 230 is disposed on at least one portion of the first semiconductor layer 220. The second semiconductor layer 240 is disposed on the active layer 230. In an embodiment, the area in dotted circle of FIG. 6A is enlarged in FIGS. 21A and 21B. FIGS. 21A and 21B each shows when the top surface is an inclined surface, the patterned structure 202 has a plurality of pointed portions 204 whose center lines C are substantially perpendicular to the top surface 212 (FIG. 21A) or the bottom surface 214 (FIG. 21B). In another embodiment of FIG. 6C, when the top surface is a curved surface 212c, the patterned structure 202 has a plurality of pointed portions 204 whose center lines C are substantially perpendicular to a corresponding tangential line T of the curved surface 212c.

In an embodiment of FIG. 6B, the top surface 212 has an inclined indentation portion 211 (or an inclined protruding portion, as shown in FIG. 2B). The inclined indentation portion 211 has a first inclined surface 212a and a second inclined surface 212b connected at an intersection line, as the same structure of FIG. 2A exception to the patterned structure 202 thereon. The patterned structure 202 has a plurality of pointed portions 204 whose center lines C are substantially perpendicular to the first inclined surface 212a or the second inclined surface 212b.

Referring to FIGS. 7A-7C. FIGS. 7A-7C are cross-sectional views showing a semiconductor light emitting structure according to an embodiment of the invention. When the top surface 212 has an inclined indentation portion 211 (or an inclined protruding portion, as shown in FIG. 2B), the patterned structure 202 includes a plurality of micro lens 205 protruding from or indenting into the top surface 212. The geometric shape of the micro lens 205 can be semi-circular, taper, rectangular, or trapezoid, for example. In an embodiment of FIG. 7B, a bragg reflecting layer 206 is further formed on the top surface 212 of the substrate 210 to increase the light extraction efficiency.

Referring to FIGS. 8A-8F. FIGS. 8A-8F are cross-sectional views showing a semiconductor light emitting structure according to an embodiment of the invention. There are a plurality of pillar portions 207a whose top surfaces are separated respectively by a plurality of slots 207b between two neighbor pillar portions 207a. All top surfaces of the pillar portions 207a are shaped in a form of curve or taper configuration and the height of each pillar portion 207a is gradually varied. In an embodiment of FIGS. 8A-8C, the overall profile on all top surfaces of the pillar portions 207a is shaped in a form of concave curve or inclined indentation configuration, and the lowest one of the pillar portions 207a is placed nearing or at the middle of the patterned structure. In an embodiment of FIGS. 8D-8F, the overall profile on all top surfaces of the pillar portions 207a is shaped in a form of convex curve or inclined taper configuration, and the highest one of the pillar portions 207a is placed near or at the middle of the patterned structure 202.

According to the second type embodiments, the top surface 212 can be realized by an overall curved surface, an inclined surface or a zigzag surface. The patterned structure 202 can be realized by regular geometric shape and/or irregular shape, such as micro lens, pointed portions or pillar portions, which avoids the light being trapped within the substrate 210 and being reflected at the interface between the first semiconductor layer 220 and the substrate 210 when the incident angle of the transmission light is larger than a critical angle. Since the light can be emitted to the outside, the light extraction efficiency of LED is increased.

### Third Embodiments

Comparing to the earlier described embodiments, one of the electrodes may be provided at the bottom of the substrate. The below described embodiments are similar to the earlier described embodiments, but with one of the electrode place at below the bottom of the substrate.

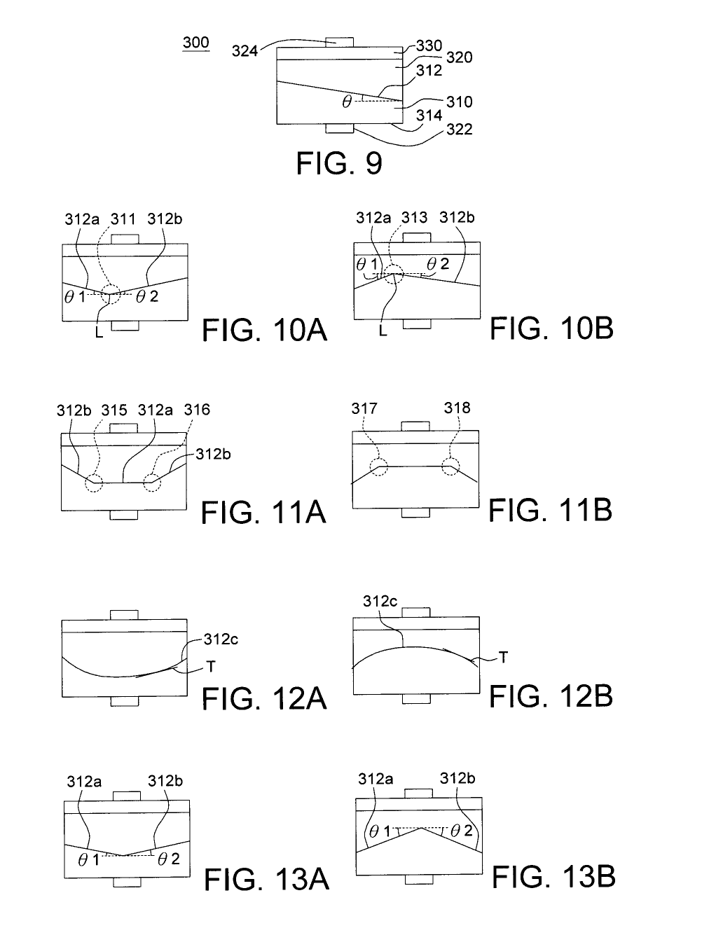

Referring to FIG. 9. FIG. 9 is a cross-sectional view showing a semiconductor light emitting structure according to an embodiment of the invention. The semiconductor light emitting structure 300 includes a first semiconductor layer 310, an active layer 320, a second semiconductor layer 330 and two opposite side electrodes 322 and 324. The electrode 322 is disposed on the bottom surface 314 of the first semiconductor layer 310. The electrode 324 is disposed on the top of the second semiconductor layer 330. The first semiconductor layer 310 has a top surface 312 and a bottom surface 314. The top surface 312 is not parallel to the bottom surface 314. The active layer 320 is disposed on the top surface 312 of the first semiconductor layer 310. The second semiconductor layer 330 is disposed on the active layer 320. In an embodiment, the top surface 312 is an inclined surface, which inclines to the right (or to the left). The inclined angle θ of the top surface 312 is about 5˜30 degree or more relative to the bottom surface 314. The light emitting from the inclined top surface 312 will be transmitted to left side or right side of the semiconductor light emitting structure 300 to avoid the electrodes 322 and 324 on the top side or the bottom side of the semiconductor light emitting structure 300.

Referring to FIGS. 10A and 10B. FIGS. 10A and 10B are cross-sectional views showing a semiconductor light emitting structure according to an embodiment of the invention. The semiconductor light emitting structure of the present embodiment is formed in the similar manner as the semiconductor light emitting structure 300 of FIG. 9, wherein same indicated references are omitted. The different between embodiments is that the top surface has an inclined indentation portion 311 or an inclined protruding portion 313, which inclines to the left and to the right. The indentation portion 311 or the protruding portion 313 has a first inclined surface 312a and a second inclined surface 312b connected at an intersection line L. The inclined angles θ1 and θ2 of the first inclined surface 312a and the second inclined surface 312b are about 5˜30 degree or more relative to the bottom surface 314. The light emitting from the inclined top surface will be transmitted to left side and right side of the semiconductor light emitting structure 300 to avoid the electrodes 322 and 324 on the top side and the bottom side of the semiconductor light emitting structure 300.

Referring to FIGS. 11A and 11B. FIGS. 11A and 11B are cross-sectional views showing a semiconductor light emitting structure according to an embodiment of the invention. The semiconductor light emitting structure of the present embodiment is formed in the similar manner as the semiconductor light emitting structure 300 of FIG. 9, wherein same indicated references are omitted. The different part between embodiments is that the top surface is a zigzag surface, which has two inclined indentation portions 315-316 or two inclined protruding portions 317-318, but the number is not limited. Each of the indentation portions 315-316 or the protruding portions 317-318 has a first inclined surface 312a and a second inclined surface 312b connected at a respective intersection line L. The inclined angles of the first inclined surface and the second inclined surface are about 5˜30 degree or more. The light emitting from the zigzag top surface will be transmitted to left side and right side of the semiconductor light emitting structure 300 to avoid the electrodes 322 and 324 on the top side and bottom side of the semiconductor light emitting structure 300.

Referring to FIGS. 12A and 12B. FIGS. 12A and 12B are cross-sectional views showing a semiconductor light emitting structure according to an embodiment of the invention. The semiconductor light emitting structure of the present embodiment is formed in the similar manner as the semiconductor light emitting structure of FIG. 9. The different part between embodiments is that the top surface is a curved surface 312c. The slop on each tangential line T of the curved surface 312c is gradually increased or decreased from one side to another side to form a concave curve or a convex curve, as shown in FIGS. 12A and 12B. The inclined angle of the slope on each tangential line T of the curve surface 312c is in the range of about 0˜30 degree or more relative to the bottom surface 314. The light emitting from the curve surface 312c will be transmitted to left side and right side of the semiconductor light emitting structure 300 to avoid the electrodes 322 and 324 on the top side and the bottom side of the semiconductor light emitting structure 300.

Referring to FIGS. 13A and 13B. FIGS. 13A and 13B are cross-sectional views showing a semiconductor light emitting structure according to an embodiment of the invention. Exception that FIGS. 10A and 10B show the first inclined surface 312a and the second inclined surface 312b have different inclined angles, that is, θ1≠θ2, the semiconductor light emitting structure of the present embodiment shows that the indentation portion 311 or the protruding portion 313 is located in middle of the first semiconductor layer 110 and the first inclined surface 312a and the second inclined surface 312b have the same inclined angle, that is, θ1=θ2. The inclined angles of the first inclined surface 312a and the second inclined surface 312b is about 5˜30 degree or more relative to the bottom surface 314.

According to the third type embodiments, the top surface 312 of the first semiconductor layer 310 can be realized by a curved surface, an inclined surface or a zigzag surface. Since the interface between the first semiconductor layer 310 and the active layer 320 is not a horizontal plane, the light reflected by the electrode is reduced, and the light scattering and transmitting to outside is notably increased so that the light extraction efficiency increases accordingly.

### Fourth Type Embodiments

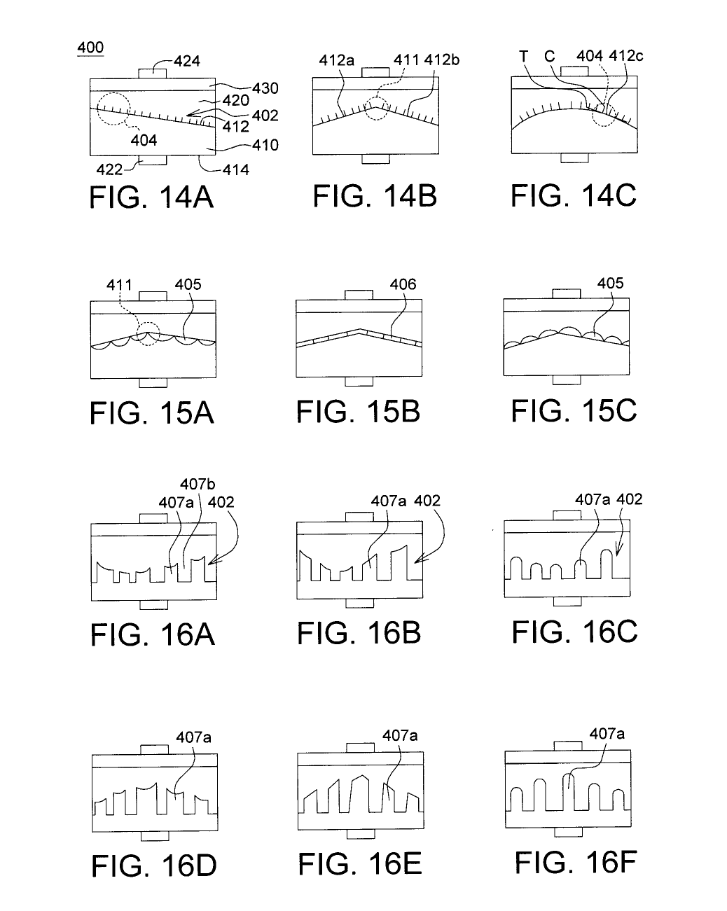

Referring to FIGS. 14A-14C. FIGS. 14A-14C are cross-sectional views showing a semiconductor light emitting structure according to an embodiment of the invention. The semiconductor light emitting structure 400 includes a first semiconductor layer 410, a patterned structure 402, an active layer 420, a second semiconductor layer 430 and two opposite side electrodes 422 and 424. The first semiconductor layer 410 has a top surface 412 and a bottom surface 414. The top surface 412 is not parallel to the bottom surface 414. The top surface 412 can be realized by a curved surface, an inclined surface or a zigzag surface. The patterned structure 402 protrudes from or indents into the top surface 412 to rough the top surface 412. The active layer 420 is disposed on the roughed top surface 412 of the first semiconductor layer 410. The second semiconductor layer 430 is disposed on the active layer 420. In an embodiment, the area in dotted circle of FIG. 14A is enlarged in FIGS. 21A and 21B. Please refer to FIGS. 21A and 21B, when the top surface 412 is an inclined surface, the patterned structure 402 has a plurality of pointed portions 404 whose center lines C are substantially perpendicular to the top surface 412 (FIG. 21A) or the bottom surface 414 (FIG. 21B). In another embodiment of FIG. 14C, when the top surface is a curved surface 412c, the patterned structure 402 has a plurality of pointed portions 404 whose center lines C are substantially perpendicular to a corresponding tangential line T of the curved surface 412c.

In an embodiment of FIG. 14B, the top surface has an inclined protruding portion 411 (or an inclined indentation portion, as shown in FIG. 10A). The inclined protruding portion 411 has a first inclined surface 412a and a second inclined surface 412b connected at an intersection line, as the same structure of FIG. 10B exception to the patterned structure 402 thereon. The patterned structure 402 has a plurality of pointed portions 404 whose center lines C are substantially perpendicular to the first inclined surface 412a or the second inclined surface 412b.

Referring to FIGS. 15A and 15C. FIGS. 15A and 15C are cross-sectional views showing a semiconductor light emitting structure according to an embodiment of the invention. When the top surface 412 has an inclined protruding portion 411 (or an inclined indentation portion, as shown in FIG. 10A), the patterned structure 402 includes a plurality of micro lens 405 protruding from or indenting into the top surface 412. The geometric shape of the micro lens 405 can be semi-circular, taper, rectangular, or trapezoid, for example. In an embodiment of FIG. 15B, a bragg reflecting layer 406 is further formed on the top surface 412 of the first semiconductor layer 410 to increase the light extraction efficiency.

Referring to FIGS. 16A-16F. FIGS. 16A-16F are cross-sectional views showing a semiconductor light emitting structure according to an embodiment of the invention. There is a plurality of pillar portions 407a whose top surfaces are separated respectively by a plurality of slots 407b between two neighbor pillar portions 407a. All top surfaces of the pillar portions 407a are shaped in a form of curve or taper configuration and the height of each pillar portion 407a is gradually varied. In an embodiment of FIGS. 16A-16C, the profile on all top surfaces of the pillar portions 407a is shaped in a form of concave curve or inclined indentation configuration, and the lowest one of the pillar portions 407a is placed in the middle of the patterned structure 402. In an embodiment of FIGS. 16D-16F, the profile on all top surfaces of the pillar portions 407a is shaped in a form of convex curve or inclined taper configuration, and the highest one of the pillar portions 407a is placed in the middle of the patterned structure 402.

According to the fourth embodiments, the top surface 412 can be realized by a curved surface, an inclined surface or a zigzag surface. The patterned structure 402 can have regular geometric shape and/or irregular shape, such as micro lens, taper portions or pillar portions, which avoids the light being trapped within the first semiconductor layer 410 and being reflected at the interface between the first semiconductor layer 410 and the active layer 420 when the incident angle of the transmission light is larger than a critical angle. Since the light can be emitted to the outside, the light extraction efficiency of LED is increased.

Referring to FIG. 17A-17H. FIGS. 17A-17H are top views showing a semiconductor light emitting structure according to the first embodiments of the invention. The top surface 112 has a plurality of contour lines P1-P3. The contour lines P1-P3 are arranged in a rectangular form or in a straight line respectively, which show the difference in elevation between successive contour lines P1-P3. According to the contour lines P1-P3 and the position of electrodes 122 and 124, the steepness of slope and profile of the top surface 112 are mapped to achieve optimum effect of the light extraction efficiency. In an embodiment as showed in FIGS. 17A, 17C and 17H, one electrode 124 is disposed above the highest or lowest contour line P3. In an embodiment as shown in FIGS. 17B, 17F and 17G, two electrodes 122 and 124 are disposed above the same contour line P3. In an embodiment as shown in FIGS. 17D and 17E, two electrodes 122 and 124 are disposed above two different contour lines P1 and P2, respectively.

Referring to FIG. 18A-18E. FIGS. 18A-18E are top views showing a semiconductor light emitting structure according to the third embodiments of the invention. The top surface 312 of the first semiconductor layer has a plurality of contour lines P1-P2. The contour lines P1-P2 are arranged in a rectangular form or a circular form, which show the difference in elevation between successive contour lines P1-P2. According to the contour lines P1-P2 and the position of one electrode 324, the steepness of slope and profile of the top surface 312 are mapped to achieve optimum effect of the light extraction efficiency. In an embodiment as showed in FIGS. 18A-18E, one electrode 324 is disposed above the highest or lowest contour line P2. The number of contour lines P1-P2 is not limited.

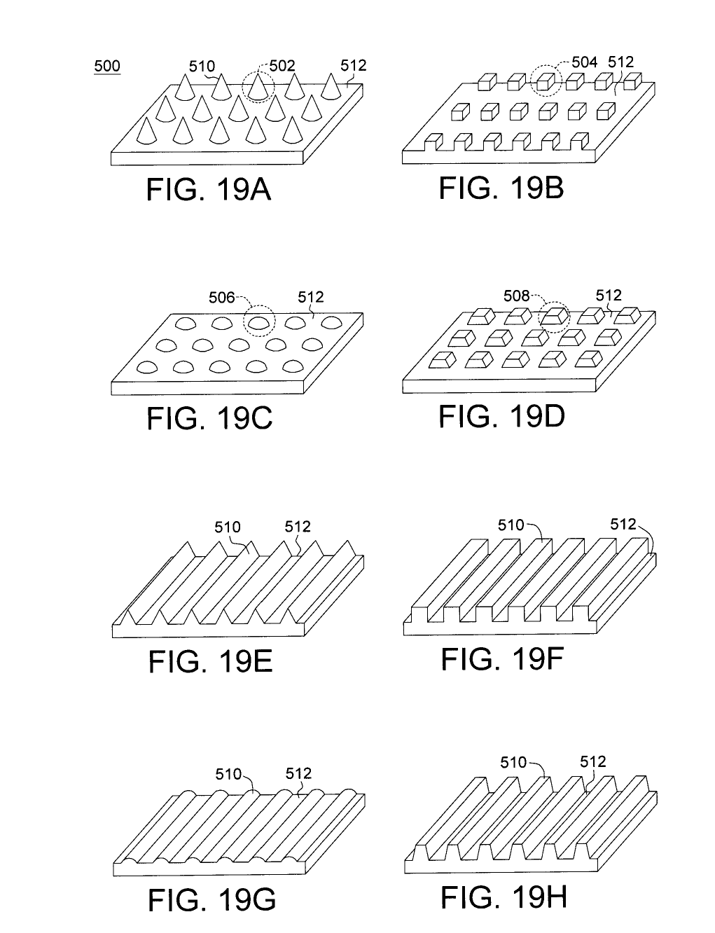

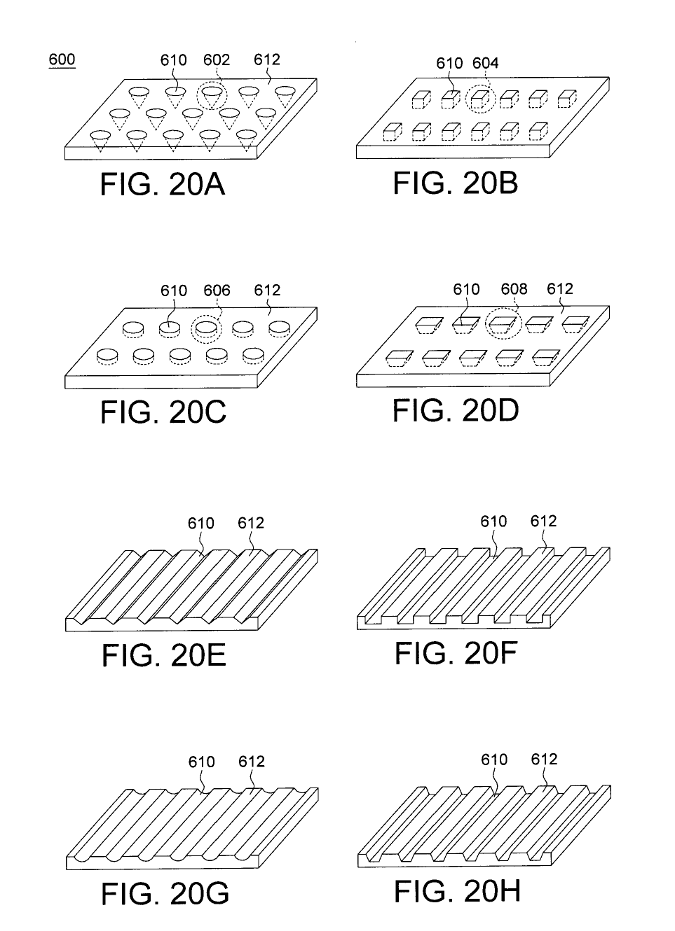

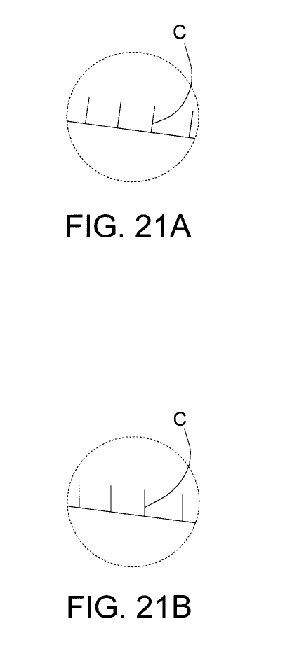

Referring to FIGS. 19A-19H and 20A-20H, various embodiments of micro-textured surfaces are illustrated. FIGS. 19A-19H and 20A-20H are schematic views showing a patterned micro-structured surface according to an embodiment of the invention. The patterned structure 500 comprises isolated, three-dimensionally varying micro structures, each having a geometric shape, which includes cone 502, tetragon 504, semi-ball 506, trapezoid 508 or combination thereof. In an embodiment of FIGS. 19A-19D, there is a plurality of protrusions 510 on the top surface 512. The protrusions 510 are regularly arranged in a form of island. In an embodiment of FIGS. 19E-19H, the patterned surface comprises two-dimensionally varying micro-structures, in the form of a plurality of protrusions 510 on the top surface 512. The protrusions 510 are regularly arranged in a form of strip. On the other hand, the patterned structure 600 of FIGS. 20A-20H has reversed geometric shape compared to that of FIGS. 19A-19H, such as cone hole 602, tetragon hole 604, semi-curved hole 606, trapezoid hole 608 or combination thereof. In an embodiment of FIGS. 20A-20D, there is a plurality of indentations 610 on the top surface 612. The indentations 610 are regularly arranged in a form of island. In an embodiment of FIGS. 20E-20H, there is a plurality of indentations 610 (such as V-cut slots, semi-curved slots, tetragon slots or trapezoid slots) on the top surface 612. The indentations 610 are regularly arranged in a form of strip.

The patterned structure can be realized by geometric shape, in a regular, irregular, quasi-regular, orderly, quasi-orderly, random, or quasi-random arrangement. The patterned structure may include a single type of micro-structures, or a combination of two or more types of micro-structures. For example, there are a first kind of protrusions (such as cones) and a second kind of protrusions (such as semi-ball) on the top surface in a form of island. For example, there are a plurality of protrusions (such as cones or semi-ball) and a plurality of indentations (such as cone hole) on the top surface in a form of island. For example, there are a first kind of protrusions (such as cones), a second kind of protrusions (such as semi-ball) and a plurality of indentations (such as V-cut slot or semi-curved slot) on the top surface in a form of island and strip. However, such exemplification is not for limiting the invention. In other implementations, the arrangement of patterned structure can be modified according to the actual necessary.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor light emitting structure, comprising:
a substrate having a top surface;
a light emitting element supported on the top surface of the substrate, wherein the light emitting element comprises an active layer having a light emitting surface facing the top surface of the substrate, wherein at least a portion of the top surface is an inclined surface at an angle relative to the light emitting surface; and
first and second electrodes positioned relative to the light emitting element.

2. The semiconductor light emitting structure as in claim 1, wherein the angle is about 5 to 30 degrees.

3. The semiconductor light emitting structure as in claim 1, wherein the inclined surface is at least part of a flat surface.

4. The semiconductor light emitting structure as in claim 3, wherein the flat surface comprises at least two inclined surfaces, each inclined relative to the light emitting surface.

5. The semiconductor light emitting structure as in claim 4, wherein each flat surface is inclined at a different angle relative to the light emitting surface.

6. The semiconductor light emitting structure as in claim 3, wherein the flat surface is at least part of an overall curved surface profile.

7. The semiconductor light emitting structure as in claim 6, wherein the curved surface profile has tangents ranging from 0 to 30 degrees.

8. The semiconductor light emitting structure as in claim 6, wherein the curved surface profile comprises facets.

9. The semiconductor light emitting structure as in claim 6, wherein the curved surface profile comprises a convex or a concave surface profile in reference to the substrate.

10. The semiconductor light emitting structure as in claim 6, wherein the curved surface profile comprises a zigzag surface profile.

11. The semiconductor light emitting structure as in claim 10, wherein the zigzag surface profile comprises a concave surface profile and a convex surface profile in reference to the substrate.

12. The semiconductor light emitting structure as in claim 1, wherein the inclined surface is at least part of a curved surface.

13. The semiconductor light emitting structure as in claim 12, wherein the curved surface comprises a convex or a concave surface in reference to the substrate.

14. The semiconductor light emitting structure as in claim 12, wherein the curved surface comprises facets.

15. The semiconductor light emitting structure as in claim 1, wherein the inclined surface is at least part of a surface structure formed at the top of the substrate.

16. The semiconductor light emitting structure as in claim 15, wherein the surface structure is at least part of a textured surface.

17. The semiconductor light emitting structure as in claim 16, wherein the textured surface comprises microstructures.

18. The semiconductor light emitting structure as in claim 17, wherein the textured surface is formed by roughening a surface.

19. The semiconductor light emitting structure as in claim 16, wherein the textured surface comprises cone, tetragon, semi-ball, trapezoid or combination thereof.

20. The semiconductor light emitting structure as in claim 1, wherein the first and second electrodes are both disposed above/on the light emitting element.
